(19) United States
(12) Patent Application Publication
(10) Pub. No.: US 2008/0124916 A1
(43) Pub. Date: May 29, 2008

(54) Method of Manufacturing Semiconductor Device

(76) Inventor: JI HO HONG, Hwaseong-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/932,542

(22) Filed: Oct. 31, 2007

(30) Foreign Application Priority Data
Nov. 27, 2006 (KR) 10-2006-0117459

(51) Int. Cl. H01L 21/4763

(52) U.S. Cl. 438/637; 257/E21.495

(57) ABSTRACT

A method manufacturing a semiconductor device is provided. Cost can be reduced and line reliability can be improved since a step for depositing a barrier metal is not required. An interlayer insulating layer, including a contact hole, can be formed on a semiconductor substrate. A seed layer, including a first metal material and at least one additive, can be formed on the interlayer insulating layer. A thermal treatment can be performed on the seed layer to form an interface layer under the seed layer, and a second metal material can be deposited on the seed layer to form a metal line.

### CROSS-REFERENCE TO RELATED APPLICATION

The present application claims the benefit under 35 U.S.C. § 119 of Korean Patent Application No. 10-2006-0117459, filed Nov. 27, 2006, which is hereby incorporated by reference in its entirety.

### BACKGROUND

Semiconductor devices typically include interconnection lines in a multi-layered structure to allow for a high degree of integration. The lines are often formed of a metal material in order to make an electrical connection through an insulating layer, such as a pre-metallic dielectric (PMD) layer or an inter-metallic dielectric (IMD) layer.

Generally, aluminum (Al) or copper (Cu) are used as the metal material of the lines.

However, copper often diffuses into the insulating layer of the semiconductor device because of its high diffusivity. This can lead to a short-circuit between lines. Therefore, in order to attempt to inhibit the diffusion of copper, a barrier layer is typically formed before a copper line is formed.

Though semiconductor devices have been decreasing in size, forming a barrier layer in order to use a copper line typically limits size reduction of the semiconductor devices. One related art approach to overcome this limitation has been to form the lines with a small width. However, forming lines with a small width increases resistance and lowers line reliability.

Thus, there exists a need in the art for an improved semiconductor device and fabricating method thereof.

### BRIEF SUMMARY

Embodiments of the present invention provide a method of manufacturing a semiconductor device without depositing a barrier layer. The method is capable of allowing for reduced semiconductor device size and improved line reliability.

In an embodiment, a method of manufacturing a semiconductor device can include: forming an interlayer insulating layer on a semiconductor substrate; forming a contact hole in the interlayer insulating layer; forming a seed layer, made up of a first metal material and at least one additive, on the interlayer insulating layer; performing a thermal treatment on the seed layer to form an interface layer under the seed layer; and depositing a second metal material on the seed layer to form a metal line.

The details of one or more embodiments are set forth in the accompanying drawings and the detailed description. Other features will be apparent to one skilled in the art from the detailed description, the drawings, and the appended claims.

### BRIEF DESCRIPTION OF THE DRAWINGS

FIGS. 1A to 1F are cross-sectional views illustrating a process of manufacturing a semiconductor device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

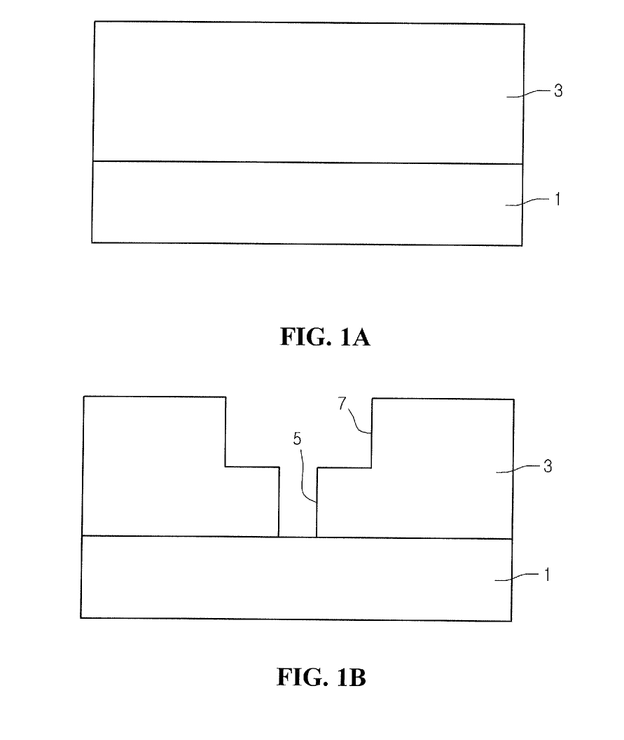

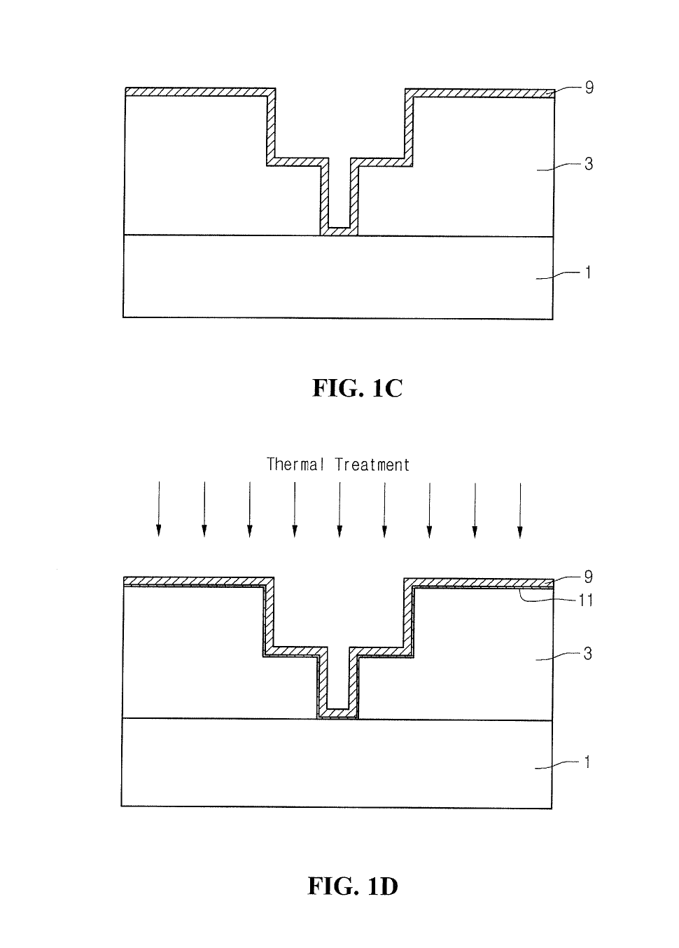

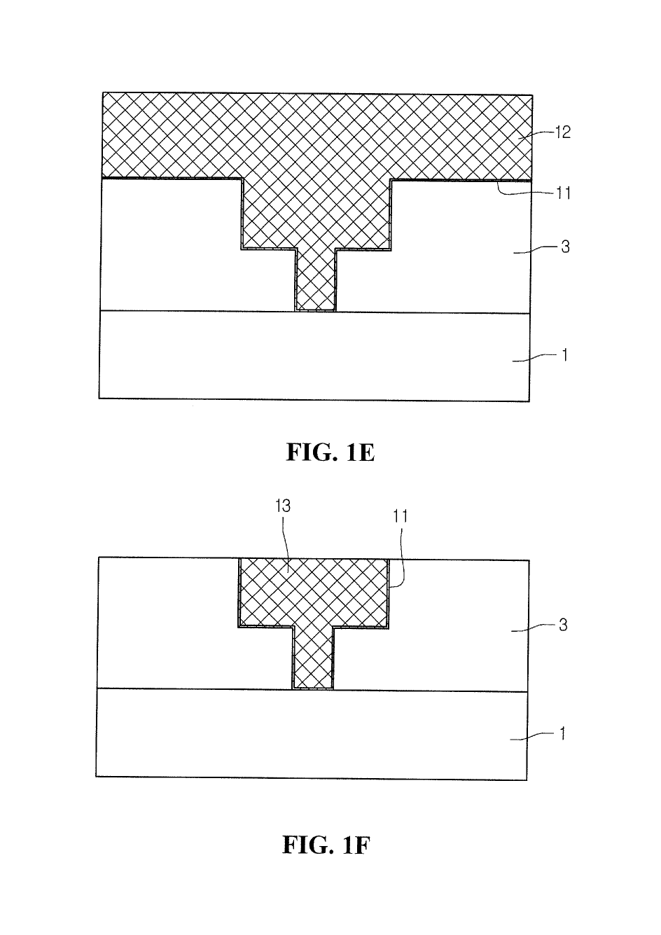

Referring to FIG. 1A, a semiconductor substrate 1 can be provided and can include a device module having a predetermined function. The device module can be any suitable module known in the art, for example, a memory device or a logic circuit. In an embodiment, the device module can be provided on the semiconductor substrate 1 to perform a driver function for providing a predetermined signal to the outside or a memory function for storing or reading information.

An interlayer insulating layer 3 can be formed on the semiconductor substrate 1. The interlayer insulating layer 3 can be formed using undoped silicate glass (USG), boron-phosphorous-doped silicate glass (BPSG), fluorine-doped silicate glass, or any other suitable material known in the art.

In an embodiment, a damascene process can be used to create a contact hole for forming a metal line. For example, the interlayer insulating layer 3 can be patterned to form a contact hole, a copper material can be used to fill the contact hole using a gap-fill process, and a chemical mechanical polishing (CMP) process can be performed to remove the copper material not in the contact hole, thereby forming a metal line.

Any damascene process known in the art can be used, such as a single damascene process or a dual damascene process. In an embodiment, a dual damascene can be used to form a via hole and a trench. A dual damascene process can be used to inhibit the formation of a void that sometimes occurs when a via hole with a small width is filled with a metal material.

Accordingly, referring to FIG. 1B, a via hole 5 and a trench 7 over the via hole 5 can be formed in the interlayer insulating layer 3 by performing a damascene process, such as a dual damascene process. The via hole 5 can have a width that is relatively small compared to the width of the trench 7. The via hole 5 and the trench 7 together may be referred to as a contact hole.

In a related art process, in order to prevent diffusion of copper, a barrier layer is typically formed in the via hole 5 and the trench 7 before forming a copper line. However, the barrier layer increases the thickness of the semiconductor device, which goes against the trend of reducing the size of semiconductor devices.

In embodiments of the present invention, a barrier layer is not deposited by performing an extra step in the fabrication process, but can be naturally formed instead.

Referring to FIG. 1C, a seed layer 9 can be formed on the interlayer insulating layer 3 including the via hole 5 and the trench 7. The seed layer 9 can also be formed on the semiconductor substrate 1 exposed by the contact hole.

The seed layer 9 can be formed by any suitable process known. In the art. In an embodiment, the seed layer 9 can be formed by performing an electroless plating process. In an electroless plating process, metal ions of a metal chloride aqueous solution can be autocatalytically reduced using a reducing agent without external electrical power, such that metal can be deposited on the surface of a material to be treated. Through an electroless plating process, a metal layer with a uniform thickness can be formed.

The seed layer 9 can be formed of copper including at least one additive. The additive or additives can be manganese (Mn), magnesium (Mg), zinc (Zn), or any other suitable additive known in the art. In an embodiment, the seed layer 9 can be formed by adding Mg to copper as an additive and performing an electroless plating process. In another embodiment, the seed layer 9 can be formed by adding Mn to copper as an additive and performing an electroless plating process. In yet another embodiment, the seed layer 9 can be formed by adding Zn to copper as an additive, and performing the electroless plating process. In a further embodiment, the seed layer 9 can be formed by adding Mn and Mg to copper as additives and performing an electroless plating process. As described above, the seed layer 9 can be formed by adding a single additive or more than one additive to copper.

In an embodiment, the additive or additives, such as Mn, Mg, or Zn, can be mixed with copper to a weight percentage of from about 0.3 wt % to about 1 wt %. If less than about 0.3 wt % of additive(s) is used, an interface layer that can form may become too thin to function as a barrier layer. If more than about 1 wt % of additive(s) is used, the interface layer that can form may become too thick to allow for a desirable overall thickness of the device.

In an embodiment, the interlayer insulating layer 3 including the via hole 5 and the trench 7 can be catalyzed to form a catalytic metal, for example, metal palladium (PdO). Then, a reducing agent can be used, without external electrical power, to autocatalytically form a plating layer on the catalyzed surface. Here, the plating layer can include copper and an additive including Mn, Mg, Zn, or any combination thereof. The reducing agent can be oxidized, thereby emitting electrons. The electrons can combine with metal ions, such as Cu²⁺, Mn²⁺, Mg²⁺, and/or Zn²⁺, thereby forming an alloy of copper and the additive or additives to form the seed layer 9 on the surface of the catalyzed metal.

Referring to FIG. 1D, a thermal treatment can be performed to form an interface layer 11 on an interface between the seed layer 9 and the interlayer insulating layer 3.

In an embodiment, the process condition of the thermal treatment can include a temperature of from about 150° C. to about 250° C. and a process time of from about 1.5 hours to about 3 hours.

The interface layer 11 can have a thickness of, for example, from about 20 Å to about 100 Å. The interface layer 11 can inhibit diffusion of copper.

The interface layer 11 can be formed on the entire interlayer insulating layer 3 under the seed layer 9, including in the via hole 5, in the trench 7, and on the semiconductor substrate 1 exposed by the contact hole.

In an embodiment, the thermal treatment causes the additive or additives included in the seed layer 9 to diffuse out. The interface layer 11 on the interface contacting the seed layer 9 can be comprised of the diffused-out additive or additives.

Referring to FIG. 1E, a metal material 12 can be deposited on the seed layer 9 to fill the via hole 5 and the trench 7 interposed with the seed layer 9. The metal material 12 can also be deposited on the portions of the seed layer 9 that are not in the via hole 5 or the trench 7. The metal material 12 can be, for example, copper. The metal material 12 can be deposited using any suitable process known in the art, such as an electro chemical plating (ECP) process.

Referring to FIG. 1F, a portion of the metal material 12 not in the via hole 5 or the trench 7 can be removed to form a metal line 13. The portion of the metal material 12 can be removed by any suitable process known in the art, for example, a chemical mechanical polishing (CMP) process.

Accordingly, in embodiments of the present invention, since the interface layer 11 can be naturally formed and can inhibit diffusion of copper, there is no need to separately form a barrier layer.

According to embodiments of the present invention, the interface layer 11 can be naturally formed during a process of forming a seed layer, such that a separate barrier layer is not required. Thus, the cost of the fabrication process of a semiconductor device can be reduced, and the process itself can be simplified. Additionally, a reduced device size can be achieved.

Any reference in this specification to “one embodiment,” “an embodiment,” example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a semiconductor device, comprising:
forming an interlayer insulating layer on a semiconductor substrate;
forming a contact hole in the interlayer insulating layer;
forming a seed layer on the interlayer insulating layer, including in the contact hole, wherein the seed layer comprises a first metal material and a first additive;
performing a thermal treatment on the seed layer to form an interface layer under the seed layer; and
depositing a second metal material on the seed layer to form a metal line.

2. The method according to claim 1, wherein the contact hole comprises a via hole.

3. The method according to claim 1, wherein the contact hole comprises a via hole and a trench over the via hole.

4. The method according to claim 1, wherein the first metal material comprises copper.

5. The method according to claim 1, wherein the second metal material comprises copper.

6. The method according to claim 1, wherein the first additive comprises manganese (Mn), magnesium (Mg), or zinc (Zn).

7. The method according to claim 6, wherein the seed layer further comprises a second additive, and wherein the second additive comprises Mn, Mg, or Zn.

8. The method according to claim 7, wherein the seed layer further comprises a third additive, and wherein the third additive comprises Mn, Mg, or Zn.

9. The method according to claim 1, wherein forming the seed layer comprises performing an electroless plating process.

10. The method according to claim 1, wherein performing the thermal treatment on the seed layer causes at least a portion of the first additive to diffuse out of the seed layer to form the interface layer.

11. The method according to claim 1, wherein the interface layer is formed on the entire semiconductor substrate, including in the contact hole.

12. The method according to claim 1, wherein the thermal treatment is performed at a temperature of about 150° C. to about 250° C. for a period of time of about 1.5 hours to about 3 hours.

13. The method according to claim 1, wherein the interface layer has a thickness of between about 20 Å and about 100 Å.

14. The method according to claim 1, wherein the first additive comprises about 0.3 wt % to about 1 wt % of the seed layer.

15. The method according to claim 1, wherein the seed layer further comprises a second additive, and wherein the first additive and the second additive together comprise about 0.3 wt % to about 1 wt % of the seed layer.

16. The method according to claim 1, wherein the seed layer further comprises a second additive and a third additive; and wherein the first additive, the second additive, and the third additive together comprise about 0.3 wt % to about 1 wt % of the seed layer.

17. The method according to claim 1, further comprising removing a portion of the second metal material that is not in the contact hole.

18. The method according to claim 17, wherein removing a portion of the second metal material comprises performing a chemical mechanical polishing (CMP) process.

19. The method according to claim 1, wherein forming the contact hole comprises performing a dual damascene process.

20. The method according to claim 1, wherein the interlayer insulating layer comprises undoped silicate glass (USG), boron-phosphorous-doped silicate glass (BPSG), or fluorine-doped silicate glass.
